(19) United States
(12) Patent Application Publication
(10) Pub. No.: US 2023/0217757 A1
(43) Pub. Date: Jul. 6, 2023

(54) DISPLAY DEVICE AND MULTI-PANEL DISPLAY DEVICE

(71) Applicant: LG DISPLAY CO., LTD., SEOUL (KR)

(72) Inventors: Jinuk LEE, Seoul (KR); JoongHa LEE, Paju-si (KR); WonGyu JEONG, Seoul (KR)

(73) Assignee: LG DISPLAY CO., LTD., SEOUL (KR)

(21) Appl. No.: 17/958,477

(22) Filed: Oct. 3, 2022

(30) Foreign Application Priority Data
Dec. 30, 2021 (KR) 10-2021-0192330

(51) Int. Cl. H01L 27/32

(52) U.S. Cl. CPC H01L 27/3279; H01L 27/3293

(57) ABSTRACT

A multi-panel display device includes a plurality of display devices disposed to be adjacent to each other, each of the plurality of display devices includes a first substrate including a display area and a non-display area enclosing the display area, a display unit including an organic light emitting diode disposed on an upper surface of the first substrate; a plurality of signal lines disposed on the upper surface of the first substrate and electrically connected to the display unit, a plurality of link lines disposed below the first substrate, a plurality of side lines disposed on a side surface of the first substrate and connects the plurality of signal lines and the plurality of link lines, and a protective layer covering the plurality of side lines and including a black material. The plurality of side lines includes a conductive particle having a particle size of 0.5 μm to 1 μm.

### CROSS-REFERENCE TO RELATED APPLICATION

This application claims the priority of Korean Patent Application No. 10-2021-0192330 filed on Dec. 30, 2021, which is hereby incorporated by reference in its entirety.

### BACKGROUND

### Field of the Disclosure

The present disclosure relates to a display device and a multi-panel display device, and more particularly, to a display device and a multi-panel display device which are capable of implementing a narrow bezel with excellent power efficiency while suppressing heat generation.

### Description of the Background

Recently, as it enters an information era, a display field which visually expresses electrical information signals has been rapidly developed, and in response to this, various display devices having excellent performances such as thin-thickness, light weight, and low power consumption have been developed. Specific examples of such a display device include a liquid crystal display device (LCD), a plasma display panel device (PDP), a field emission display device (FED), and an organic light emitting display device (OLED).

Generally, display devices include a display panel having a display area in which images are displayed and a non-display area defined along a periphery of the display area, a plurality of driving circuits disposed in the non-display area, and a printed circuit board (PCB) which supplies control signals to the plurality of driving circuits. A plurality of link lines which connects the display panel and the driving circuits are disposed in the non-display area. The non-display area is blocked by a black matrix of the display panel or a case so that the images are not substantially displayed so that this area is generally referred to as a bezel area. In order to increase an effective display screen size with the same area, the driving circuits and the link lines are disposed in a lower portion of the display panel corresponding to the non-display area and a side line is disposed on a side surface to electrically connect the display panel and the driving circuits.

In the meantime, the size and the shape of the display are gradually being diversified and in recent years, extra-large displays are attracting attention. In the ultra-large displays, it is difficult to implement an ultra-large screen with one panel, so that a multi-display panel display device in which a plurality of display panels is connected is being used. Such a multi-panel display device may implement an ultra-large screen by disposing a plurality of display panels in a tile pattern. However, in the multi-panel display device, seams are formed between the connected display panels due to bezel areas of the adjacent display panels. The seams are visibly recognized by the user so that when one image is displayed on the entire screen, a sense of disconnection and awkwardness may be felt. Accordingly, a bezel area of each display panel needs to be minimized.

Simultaneously, since the luminance and the circuit integration become higher, a power consumption is significant, so that the multi-panel display device needs to be designed to improve a power efficiency and also needs to be designed to solve the problem that heat generation increases as power consumption increases.

### SUMMARY

Accordingly, the present disclosure is to provide a display device and a multi-panel display device which are capable of implementing a narrow bezel with excellent power efficiency and high reliability.

The present disclosure is also to provide a structure which lowers a contact resistance of a side line and solves a heat generation problem which is generated on a side line portion of the display device.

The present disclosure is not limited to the above-mentioned and other features, which are not mentioned above, can be clearly understood by those skilled in the art from the following descriptions.

According to an aspect of the present disclosure, a display device includes a first substrate including a display area and a non-display area enclosing the display area, a display unit including an organic light emitting diode disposed on an upper surface of the first substrate; a plurality of signal lines disposed on the upper surface of the first substrate and electrically connected to the display unit, a plurality of link lines disposed below the first substrate, and a plurality of side lines disposed on a side surface of the first substrate and connecting the plurality of signal lines and the plurality of link lines, and the plurality of side lines includes a conductive particle having a particle size of 0.5 μm to 1 μm.

According to an aspect of the present disclosure, a multi-panel display device includes: a plurality of display devices disposed to be adjacent to each other. Each of the plurality of display devices includes: a first substrate including a display area and a non-display area enclosing the display area, a display unit including an organic light emitting diode disposed on an upper surface of the first substrate; a plurality of signal lines disposed on the upper surface of the first substrate and electrically connected to the display unit, a plurality of link lines disposed below the first substrate, a plurality of side lines disposed on a side surface of the first substrate and connecting the plurality of signal lines and the plurality of link lines, and a protective layer covering the plurality of side lines and including a black material. The plurality of side lines includes a conductive particle having a particle size of 0.5 μm to 1 μm.

Other detailed matters of the exemplary aspects are included in the detailed description and the drawings.

According to the present disclosure, in the display device, the mechanical property and the heat resistance may be improved while lowering a contact resistance of the side line. Accordingly, the power efficiency and the reliability of the display device are improved.

According to the present disclosure, a multi-panel display device which reduces a bezel area to improve the image quality and reduce the power consumption may be provided.

According to the present disclosure, deterioration of a side line is solved to provide a multi-panel display device with excellent reliability.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view of a display device according to an aspect of the present disclosure;

FIG. 2 is a top view of a first substrate in a display device according to an aspect of the present disclosure;

FIG. 3 is a side view of a display device according to an aspect of the present disclosure;

FIG. 4 is a graph measuring a contact resistance of a wiring line according to a size of conductive particles which form a side line of the display device according to an aspect of the present disclosure;

FIG. 5A is an image obtained by photographing a cross-section of a side line according to a comparative example 2;

FIG. 5B is an image obtained by photographing a cross-section of a side line according to a comparative example 1;

FIG. 6 is a cross-sectional view of a display device according to another aspect of the present disclosure;

FIG. 7 is a side view of a display device according to another aspect of the present disclosure;

FIG. 8 is a plan view of a multi-panel display device according to an aspect of the present disclosure;

FIG. 9 is an enlarged plan view of region “X” of FIG. 8; and

FIG. 10 is a cross-sectional view taken along line I-I′ of FIG. 9.

### DETAILED DESCRIPTION

Advantages and characteristics of the present disclosure and a method of achieving the advantages and characteristics will be clear by referring to aspects described below in detail together with the accompanying drawings. However, the present disclosure is not limited to the aspects disclosed herein but will be implemented in various forms. The aspects are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure can be partially or entirely adhered to or combined with each other and can be interlocked and operated in technically various ways, and the aspects can be carried out independently of or in association with each other.

Throughout the specification, unless otherwise specified, a particle size is a particle size at a point (D50) at which an accumulated volume is 50% in an accumulative particle size distribution.

Hereinafter, an aspects of the present disclosure will be described in detail with reference to accompanying drawings.

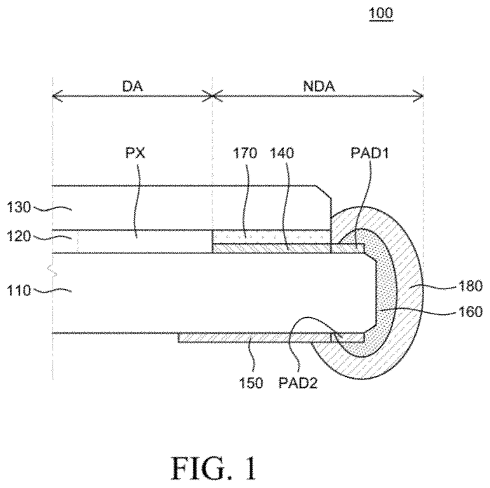

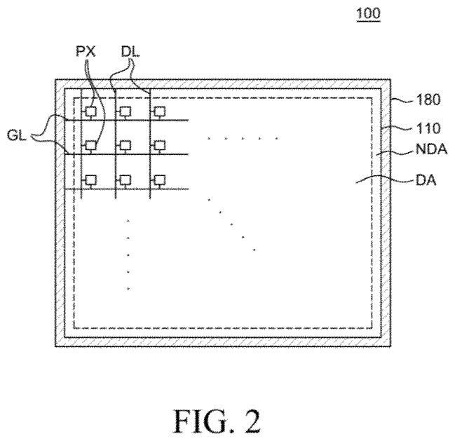

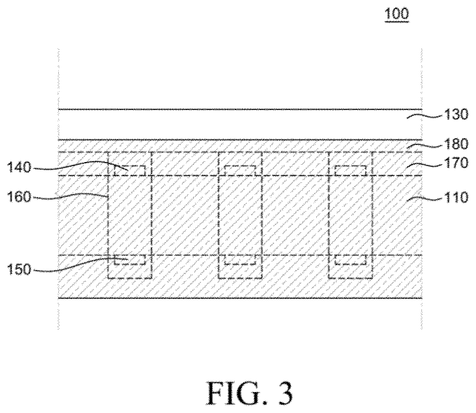

FIGS. 1 to 3 are views for explaining a display device according to an aspect of the present disclosure. FIG. 1 is a schematic cross-sectional view of a display device according to an aspect of the present disclosure. FIG. 2 is a schematic top view of a first substrate in a display device according to an aspect of the present disclosure. FIG. 3 is a side view of a display device according to an aspect of the present disclosure.

Referring to FIGS. 1 to 3, a display device 100 according to the aspect of the present disclosure includes a first substrate 110, a display unit 120, a sealant 170, a second substrate 130, a signal line 140, a link line 150, a side line 160, and a protective layer 180.

The first substrate 110 is a base substrate for supporting various components of the display unit. The first substrate 110 may be formed of an insulating material. For example, the first substrate 110 may be a glass or plastic material. The first substrate 110 may be a plastic film having a flexibility so as to be bendable as needed.

In the first substrate 110, a display area DA and a non-display area NDA enclosing the display area DA may be defined. The display area DA is an area where images are actually displayed in the display device and in the display area DA, the display unit 120 which will be described below is disposed. The non-display area NDA is an area where images are not actually displayed so that the non-display area NDA may be defined as an edge area of the first substrate 110 which encloses the display area DA. In the non-display area NDA, various wiring lines, such as a gate line and a data line which are connected to the thin film transistor of the display unit 120 disposed in the display area DA, may be disposed. Further, in the non-display area NDA, a driving circuit, for example, a data driving integrated circuit chip or a gate driving integrated circuit chip may be disposed and a plurality of pads may be disposed, but is not limited thereto.

A plurality of pixels PX is defined in the display area DA of the first substrate 110. Each of the plurality of pixels PX is an individual unit which emits light and includes red, green, and blue pixels. If necessary, a white pixel may be included. In each of the plurality of pixels PX, the display unit 120 is formed.

The display unit 120 displays images. For example, the display unit 120 includes an organic light emitting diode and a circuit unit for driving the organic light emitting diode. Specifically, the organic light emitting diode may include an anode, at least one organic layer, and a cathode so that electrons and holes are coupled to emit light. The organic layer includes an organic light emitting layer, and additionally includes a hole injection layer, a hole transport layer, an electron transport layer, and an electron injection layer, but is not limited thereto. For example, the circuit unit may include a plurality of thin film transistors, a capacitor, and a plurality of wiring lines to drive the organic light emitting diode.

When the display device 100 is driven in a top emission manner, the circuit unit is disposed on the first substrate 110 and the organic light emitting diode is disposed on the circuit unit. Specifically, the thin film transistor is disposed on the first substrate 110, a planarization layer is disposed on the thin film transistor, and the anode, the plurality of organic layers including an organic light emitting layer, and the cathode are sequentially disposed on the planarization layer to configure the display unit 120.

As another example, the display unit 120 includes a liquid crystal display element and a circuit unit. Specifically, the liquid crystal display element includes a back light and a liquid crystal layer and displays images by adjusting an optical transmittance of liquid crystals.

The second substrate 130 is disposed on the display unit 120 to be opposite to the first substrate 110. The second substrate 130 is an encapsulation substrate which protects the display unit 120 from moisture or air permeating from the outside or a physical impact. For example, the second substrate 130 may be selected from a metal foil and a plastic substrate, but is not limited thereto and may be an encapsulation layer formed by being coated with an organic material and/or an inorganic material.

The sealant 170 is disposed between the first substrate 110 and the second substrate 130 in the non-display area NDA. The sealant 170 is disposed to enclose an outer periphery of the display unit 120 and bonds the first substrate 110 and the second substrate 130. The sealant 170 blocks moisture and oxygen permeating from a side surface of the display unit 120 and is referred to as a dam. When the second substrate 130 does not have a plate shape, such as glass, metal foil, or a plastic substrate, but may be an encapsulation layer formed to be coated with an organic material and/or an inorganic material, the sealant 170 may be omitted.

The plurality of signal lines 140 is disposed on an upper surface of the first substrate 110 and the plurality of link lines 150 is disposed on a rear surface of the first substrate 110. The plurality of signal lines 140 is electrically connected to the component of the display unit 120 to transmit a signal to the display unit 120. The plurality of link lines 150 is wiring lines which connect the plurality of signal lines formed on the upper surface of the first substrate 110 and the driving circuit.

Specifically, referring to FIGS. 1 and 2 together, the plurality of signal lines 140 disposed on the upper surface of the first substrate 110 may be a plurality of gate lines GL and a plurality of data lines DL. The plurality of gate lines GL and the plurality of data lines DL are electrically connected to the thin film transistor of the display unit 120 disposed in the display area DA to transmit a gate signal and a data signal.

In the meantime, the plurality of link lines 150 disposed on the rear surface of the first substrate 110 may be a plurality of gate link lines and a plurality of data link lines. The plurality of gate link lines is wiring lines which connect the plurality of gate lines GL disposed on the upper surface of the first substrate 110 and the gate driving circuit. The plurality of data link lines is wiring lines which connect the plurality of data lines DL disposed on the upper surface of the first substrate 110 and the data driving circuit. The plurality of gate link lines and the plurality of data link lines may extend from an end of the rear surface of the first substrate 110 to a center of the rear surface of the first substrate 110.

Further, on the rear surface of the first substrate 110, a gate driving circuit is disposed to be electrically connected to the plurality of gate link lines and a data driving circuit is disposed to be electrically connected to the plurality of data link lines. At this time, the gate driving circuit and the data driving circuit may be formed directly on the rear surface of the first substrate 110 and may be disposed on the rear surface of the first substrate 110 in a chip on film manner. As another example, the gate driving circuit and the data driving circuit may be connected to the printed circuit board. The printed circuit board may transmit various signals to the plurality of signal lines 140 and the display unit 120 formed on the first substrate 110.

Referring to FIG. 1, each of the plurality of signal lines 140 may include a first pad unit PAD1 and each of the plurality of link lines 150 may include a second pad unit PAD2. The first pad unit PAD1 and the second pad unit PAD2 are areas which are in contact with the side line 160. The first pad unit PAD1 may be a conductive layer extending from the plurality of signal lines 140 and the second pad unit PAD2 may be a conductive layer extending from the plurality of link lines 150. The first substrate 110 protrudes outwardly from the second substrate 130. An end of the plurality of signal lines 140 disposed on the upper surface of the first substrate 110, that is, an upper surface of the first pad unit PAD1 is exposed. Accordingly, the side line 160 which electrically connects the plurality of signal lines 140 and the plurality of link lines 150 may be in contact with not only the side surface of the signal line 140, but also the upper surface of the signal line 140. As described above, when a contact area with the signal line 140 of the side line 160 is increased, the current which is transmitted to the signal line 140 by means of the side line 160 is significantly increased. Accordingly, since the power efficiency is increased, it is easy to implement a large size display device.

Referring to FIG. 1 continuously, the plurality of side lines 160 is disposed on the side surface of the first substrate 110. The plurality of side lines 160 electrically connects the signal lines 140 disposed on the upper surface of the first substrate 110 and the link lines 150 disposed on the rear surface of the first substrate 110. The side line 160 is patterned to electrically connect the plurality of corresponding signal lines 140 and the plurality of corresponding link lines 150 to each other.

The plurality of side lines 160 is disposed to cover ends of the plurality of signal lines 140 disposed on the upper surface of the first substrate 110, the side surface of the first substrate 110, and ends of the plurality of link lines 150 disposed on the rear surface of the first substrate 110. That is, the plurality of side lines 160 is disposed to continuously cover the first pad unit PAD1 of the plurality of signal lines 140, the side surface of the first substrate 110, and the second pad unit PAD2 of the plurality of link lines 150. Further, the plurality of side lines 160 is in direct contact with the first pad unit PAD1, the side surface of the first substrate 110, and the second pad unit PAD2.

Specifically, the plurality of side lines 160 may include a first side line and a second side line. The first side line connects the gate line GL formed on the upper surface of the first substrate 110 and the gate link line formed on the rear surface of the first substrate 110. The second side line connects the data line DL formed on the upper surface of the first substrate 110 and the data link line formed on the rear surface of the first substrate 110.

The plurality of side lines 160 includes a conductive particle and a binder resin. For example, the plurality of side lines 160 may be formed by patterning the paste including conductive particles and a binder resin using a pad printing method. A step is formed on the side surface of the first substrate 110 on which the side line 160 is formed. However, the pad printing method uses a silicon rubber pad having an elasticity such as PDMS, so that the conductive line may be easily formed on a surface having a step. The thermal treatment is performed after patterning the paste. During the thermal treatment, the conductive particle is sintered and the binder resin is cured to form a side line 160 including a conductive part and a resin part. Specifically, conductive particles having a relatively small particle size may be melted by the thermal treatment. Accordingly, a conductive part which is fixed as a single mass after some of the conductive particles are melted may be formed. Further, the binder resin is cured during the thermal treatment process to form the resin part.

Specifically, the conductive particles may include one or more metals selected from silver (Ag), gold (Au), platinum (Pt), palladium (Pd), and copper (Cu). For example, the conductive particle may be silver (Ag) or an alloy thereof. This is hardly oxidized and has an excellent electric characteristic.

At this time, a particle size of the conductive particle is desirably 0.5 μm to 1 μm. When the particle size of the conductive particle satisfies this range, a contact area between the conductive particle and the wiring line or the electrode is large so that the contact resistance is small. Therefore, the electric characteristic of the side line 160 is excellent and the heat resistance may be improved. By doing this, the power consumption is reduced and the mechanical property is significantly improved so that a display device having a high reliability and excellent display quality may be provided. The conductive particle may have a single particle size distribution, and if necessary, may have a multiple particle size distribution.

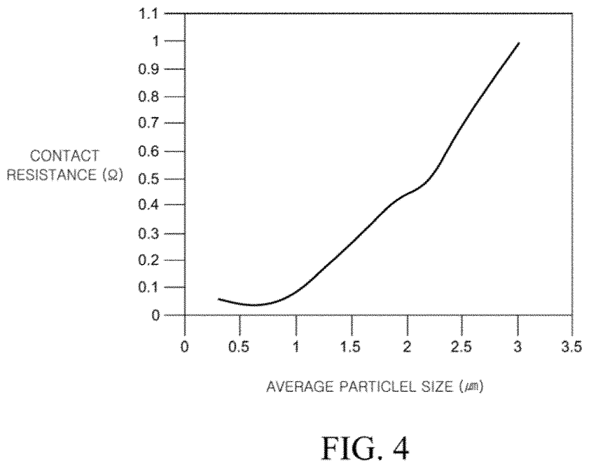

The effect according to the particle size of the conductive particle will be described in more detail with reference to FIG. 4.

FIG. 4 is a graph measuring a contact resistance of a wiring line according to a size of conductive particles which form a side line of the display device according to an aspect of the present disclosure.

Referring to FIG. 4, generally, it is confirmed that the larger the particle size of the conductive particle, the higher the contact resistance between the side line and the electrode. To be more specific, when the particle size of the conductive particle is larger than 1.0 μm, the contact area between the conductive particle and the wiring line or the electrode is small so that the contact resistance is significantly increased. That is, the contact resistance between the side line 160 and the first pad unit PAD1 of the signal line 140 and the second pad unit PAD2 of the link line 150 is increased. As the contact resistance is increased, current flowing through the signal line 140 above the side line and the plurality of link lines 150 below the side line through the side line 160 is increased to generate heat. Therefore, a fire may occur in the outer periphery of the display device 100 or burn may be caused due to the contact with the user's body.

In the meantime, generally, it is expected that the contact area between the conductive particle and the wiring line or the electrode is large so that the contact resistance is reduced. However, referring to FIG. 4, even though the particle size of the conductive particle is smaller than 0.5 μm, it is confirmed that the contact resistance is increased. During the process of forming the side line 160, the binder resin is cured by the thermal treatment. In this case, when the particle size of the conductive particle is smaller than 0.5 μm, the conductive particles are sintered due to the temperature for curing the binder resin so that the average particle size is increased. That is, the conductive particles are melted to be gathered by the thermal treatment process to form particles having a rather large particle size. By doing this, the contact resistance between the conductive particle and the wiring line or the electrode is increased.

In the meantime, the side line 160 includes conductive particles of 72 wt % to 85 wt % or 75 wt % to 85 wt % based on a sum of the conductive particles and the binder resin. When the content of the conductive particles is smaller than 72 wt %, a resistance of the side line is significantly increased and deterioration is caused by the use for a predetermined time so that the side line is disconnected or cannot perform the function. Further, when the content of the conductive particles exceeds 85 wt %, the processability is significantly lowered so that it may be difficult to form the side line.

The binder resin provides adhesiveness between interfaces to allow the side line 160 to be adhered onto a material without being peeled. For example, the binder resin may be a curable epoxy resin. The epoxy resin may improve the adhesion between the interfaces and have a strong resistance against the deformation of the stress, and protect the side line 160 from the physical impact.

The side line 160 may include a binder resin of 15 wt % to 28 wt % based on a sum of the conductive particle and the binder resin. However, a ratio of the content of the binder resin is not limited thereto and vary depending on the particle size of the conductive particle and the method of patterning the side line 160.

The side line 160 may further include a curing agent and other additives in addition to the conductive particles and the binder resin. For example, the curing agent includes isocyanate or amine based curing agent, but is not limited thereto. Further, other additives may include dispersants, additional diluents, and brighteners, but are not limited thereto.

The thickness of the side line 160 may be 1 μm to 15 μm. Within this range, it is advantageous in that a bezel area is thin and the power efficiency and the reliability are high. However, it is not limited thereto and the thickness may be adjusted if necessary.

A width of each of the plurality of side lines 160 is not specifically limited, but may be formed to be larger than the width of the signal line 140 and the link line 150 to increase the contact area between wiring lines.

The protective layer 180 is formed to cover the plurality of side lines 160. The protective layer 180 includes a black material so that the side line 160 is not visible from the outside. The plurality of side lines 160 is formed of a metal material having a glossy property such as silver (Ag), so that external light or light emitted from the display unit 120 is reflected to be recognized by the user. Therefore, the protective layer 180 is formed of an insulating material including a black material. That is, the protective layer 180 may be an insulating layer including a black material.

The display device according to the aspect of the present disclosure includes a plurality of side lines which electrically connects a plurality of signal lines disposed on an upper surface of the first substrate and a plurality of link lines disposed on a lower surface of the first substrate. At this time, each of the plurality o side lines includes a conductive particle having a particle size of 0.5 μm to 1 μm and the binder resin. The size of the conductive particle satisfies the above-mentioned range so that not only the physical characteristic of the side line formed therefrom such as an adhesiveness and the hardness, but also the electric characteristic such as a contact resistance may be improved. By doing this, the problems such as deterioration of the side line and heat generation of the display element may be solved.

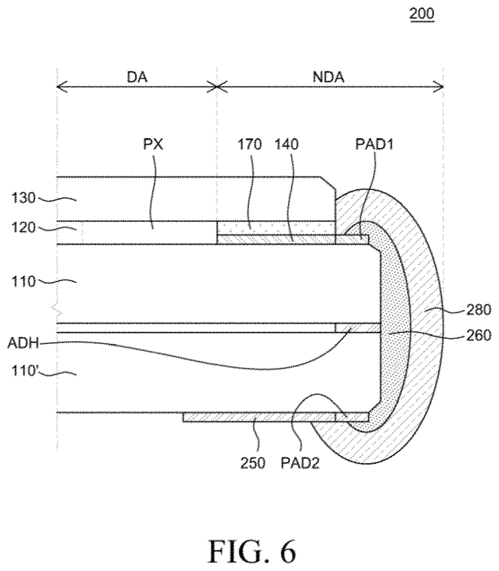

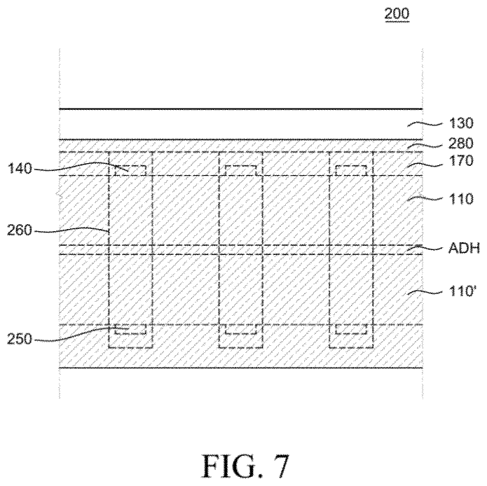

FIG. 6 is a cross-sectional view of a display device according to another aspect of the present disclosure, and FIG. 7 is a side view of a display device according to another aspect of the present disclosure. A display device 200 according to another aspect of the present disclosure includes a first substrate 110, a display unit 120, a sealant 170, a second substrate 130, a signal line 140, a link line 250, a side line 260, a protective layer 280, an adhesive layer ADH, and a third substrate 110′. As compared with the display device 100 illustrated in FIGS. 1 to 3, a display device 200 according to another aspect of the present disclosure further includes a third substrate and an adhesive layer. Therefore, the other components are substantially the same except that structures of the plurality of link lines, the plurality of side lines, and the protective layer are changed. Accordingly, a redundant description will be omitted.

Referring to FIGS. 6 to 7, a third substrate 110′ is disposed below the first substrate 110. The third substrate 110′ is an auxiliary substrate which supports components below the display device 200. The third substrate 110′ may be formed of an insulating material. For example, the third substrate 110′ may be a glass or plastic material. The third substrate 110′ may be formed of the same material as the first substrate 110.

The adhesive layer ADH is disposed between the first substrate 110 and the third substrate 110′. The adhesive layer ADH bonds the first substrate 110 and the third substrate 110′. The adhesive layer ADH is disposed between the first substrate 110 and the third substrate 110′ so as to correspond to the non-display area NDA. However, it is not limited thereto so that the adhesive layer ADH may be disposed in the entire surface with the same size as the first substrate 110 or the third substrate 110′.

In the case of the display device 100 illustrated in FIGS. 1 to 3, the display unit 120 and the plurality of signal lines 140 are disposed on an upper surface of the first substrate 110 and the link line 150 and the driving circuit are disposed on a rear surface of the first substrate 110. When components are disposed on both surfaces using one substrate as described above, during the process of disposing some components on one surface after disposing the other components on the other surface, it is difficult to secure the stability of the process.

Accordingly, the display device 200 according to another aspect of the present disclosure is manufactured by a process of bonding the first substrate 110 and the third substrate 110′ after disposing the display unit 120 and the signal line 140 on the first substrate 110 and disposing the link line 250 and the driving circuit on the third substrate 110′. Therefore, the stability of the process may be ensured. Therefore, it is possible to reduce product defects and provide the display device 200 having better quality and reliability.

The plurality of link lines 250 is formed on the rear surface of the third substrate 110′. Specifically, the plurality of gate link lines and the plurality of data link lines are formed on the rear surface of the third substrate 110′. Further, on the rear surface of the third substrate 110′, a gate driving circuit is disposed to be electrically connected to the plurality of gate link lines and a data driving circuit is disposed to be electrically connected to the plurality of data link lines.

The plurality of side lines 260 is disposed on the side surfaces of the first substrate 110 and the third substrate 110′. The plurality of side lines 260 is disposed to cover ends of the plurality of signal lines disposed on the upper surface of the first substrate 110, side surfaces of the first substrate 110 and the third substrate 110, and ends of the plurality of link lines 250 disposed on the rear surface of the third substrate 110.

The protective layer 280 is disposed on the plurality of side lines 260. The protective layer 280 is continuously disposed so as to fully cover from one end of the side line to the other end. For example, the protective layer 280 may be disposed to enclose all the side surfaces of the first substrate 110 and the third substrate 110′. That is, the protective layer 280 may be formed as one layer so as to cover all the plurality of side lines 260 which is patterned to connect the signal lines 140 and the link lines 250 which correspond to each other. However, it is not limited thereto and the protective layer 280 may be selectively patterned so as to correspond to the plurality of side lines 260.

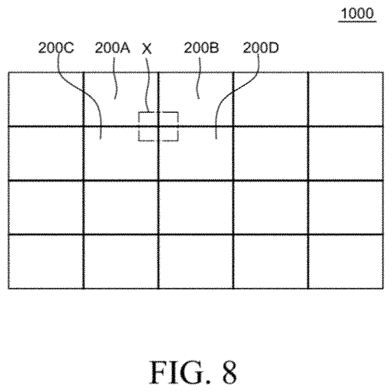

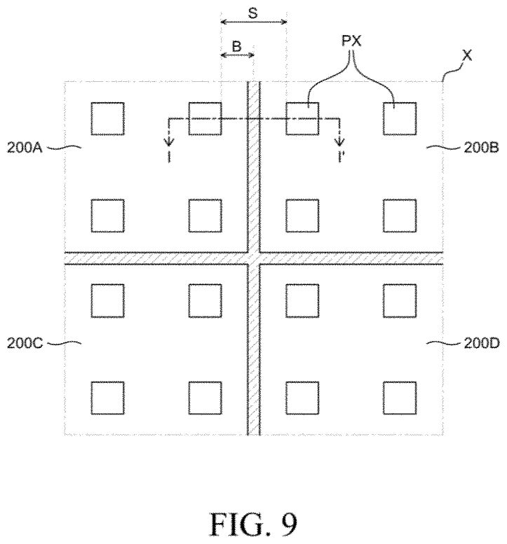

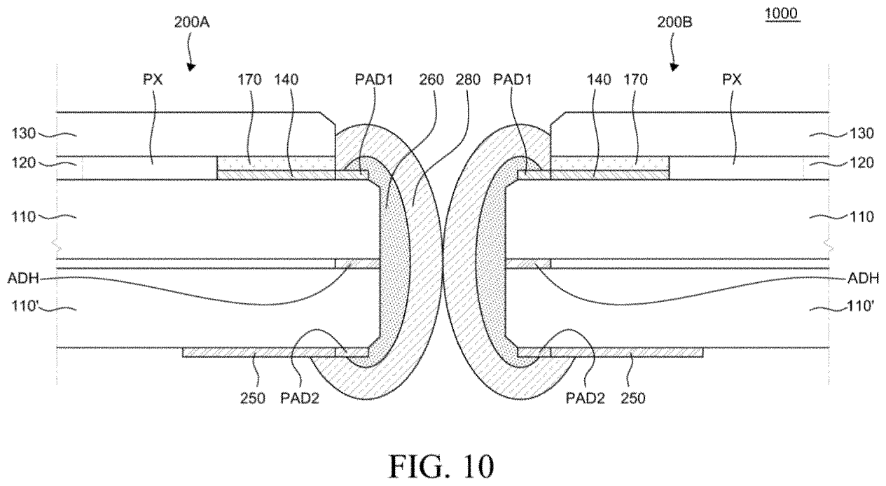

FIGS. 8 to 10 are views for explaining a multi-panel display device according to an aspect of the present disclosure. FIG. 8 is a plan view of a multi-panel display device according to an aspect of the present disclosure. FIG. 9 is an enlarged plan view of a region X of FIG. 8, and FIG. 10 is a cross-sectional view taken along the line I-I′ of FIG. 9.

Referring to FIG. 8, a multi-panel display device 1000 according to an aspect of the present disclosure includes a plurality of display devices 200A, 200B, 200C, and 200D. The plurality of display devices 200A, 200B, 200C, and 200D is disposed in a m×n tile pattern to be implemented as one multi-panel display device 1000. For the convenience of description, in FIG. 8, even though it is illustrated that 20 display devices are disposed in a 5×4 tile pattern, the present disclosure is not limited thereto so that an appropriate number of display devices may be disposed as needed.

Referring to FIG. 9 which enlarges a region X of FIG. 8, the plurality of display devices may be disposed to be in contact with each other vertically or horizontally. For example, the plurality of display devices 200A, 200B, 200C, and 200D includes a first display device 200A, a second display device 200B, a third display device 200C, and a fourth display device 200D. The first display device 200A and the second display device 200B are disposed to be in contact with each other horizontally and the first display device 200A and the third display device 200C are disposed to be in contact with each other vertically.

FIG. 10 is a cross-sectional view taken along the line I-I′ of FIG. 9. Referring to FIG. 10, in the multi-panel display device 1000 according to the aspect of the present disclosure, the first display device 200A and the second display device 200B are disposed to be in contact with each other horizontally. The display devices 200A and 200B are substantially the same as the display device 200 illustrated in FIG. 6 so that a redundant description will be omitted.

Referring to FIG. 10, each of the first display device 200A and the second display device 200B include a side line 260 including conductive particles. At this time, the particle size of the conductive particle of the side line 260 may be 0.5 μm to 1 μm. As described above, when the particle size of the conductive particle satisfies 0.5 μm to 1 μm, a contact area between the conductive particle and the wiring line or the electrode is large so that the contact resistance is small. Therefore, the electric characteristic of the side line 260 is excellent and the heat resistance may be improved. Further, the surface hardness of the side line 260 is improved so that the mechanical property is also improved.

Since the multi-panel display device includes a large-area display device and includes a plurality of display devices, the luminance and a circuit integration are advanced so that the power consumption is inevitably significant. Therefore, the resistance of the side line connected to the driving circuit is increased and the temperature of the display panel is improved so that the problem of deterioration may be caused. The multi-panel display device 1000 of the present disclosure reduces the contact resistance of the side line 260 to reduce the temperature of the display panel.

Hereinafter, the effect according to the particle size of the conductive particle will be described in more detail with Example and Comparative Example. However, the following Examples are set forth to illustrate the present disclosure, but the scope of the disclosure is not limited thereto.

### Example 1

In Example 1, a paste including silver particle (80 wt %) having a particle size of 0.7 μm and an epoxy binder (20 wt %) was patterned on the glass by a pad printing manner. Next, a specimen including a silver line cured by thermally treating the patterned silver paste at 200° C. was produced (a width of a wiring line was 50 μm and a wiring interval was 50 μm).

### Comparative Example 1

In Comparative Example 1, the same specimen as Example 1 except that a particle size of the silver particle was 2.0 μm was produced.

### Experimental Example 1-Evaluation of Panel Temperature

After driving a display panel to which a side line formed by methods of Example 1 and Comparative Example 1 was applied, for one hour, a maximum temperature and an average temperature of the side unit of the panel were measured. The results were represented in the following Table 1.

TABLE 1

| Classification | Comparative Example 1 | Example 1 |
|---|---|---|
| Maximum panel | 57 | 46 |
| temperature (° C.) | | |
| Average panel temperature | 54 | 44 |
| (° C.) | | |

Referring to Table 1, when the silver line according to Example 1 was used as the side line, it was confirmed that a temperature reduction effect of approximately 10° C. was obtained. That is, when the conductive particle was equal to or smaller than 1 μm, the heat generation of the panel may be significantly reduced by the effect of reducing the contact resistance.

### Comparative Example 2

In Comparative Example 2, the same specimen as Example 1 except that a particle size of the silver particle was 0.3 μm was produced.

### Experimental Example 2-Cross-Section Analysis

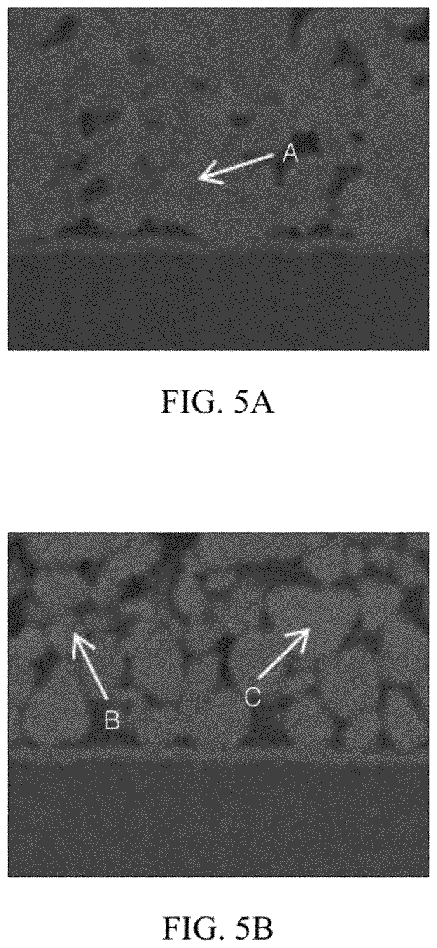

A cross-section of the silver line produced by Comparative Example 2 and Experimental Example 1 was photographed to analyze particle sizes. FIG. 5A is an image obtained by photographing a cross-section of a side line according to a comparative example 2. FIG. 5B is an image obtained by photographing a cross-section of a side line according to a comparative example 1.

First, referring to FIG. 5A, in Comparative Example 2, a portion A in which the conductive particles were sintered after the heating and curing process of the paste to identify a part A whose particle sizes was significantly increased. However, referring to FIG. 5B, in Example 1, some of the conductive particles were sintered so that the particle size is slightly increased (B). However, it was confirmed that there may be a portion C in which the sintering was not performed. That is, when FIGS. 5A and 5B were compared, in Comparative Example in which the particle size of the conductive particle was smaller than 0.5 μm, the conductive particles were sintered after the process of heating and curing processes of the paste. Therefore, it was confirmed that the average particle size was increased more than the side line formed as an example including a conductive particle having a particle size of 0.7 μm.

### Experimental Example 3-Contact Resistance

A contact resistance was measured at the room temperature using a four-point probe type surface resistance measuring unit. At the same thermal treatment temperature of 200° C., when the thermal treatment times were 30 minutes, 60 minutes, and 180 minutes, the contact resistance was measured. The results were represented in the following Table 2.

### Experimental Example 4-Surface Hardness

A surface of specimen was scratched by a pencil while applying a load of 500 g to a specimen produced in Example 1 and Comparative Example 2 and then a scratch of the surface was measured with the naked eye. At the same thermal treatment temperature of 200° C., when the thermal treatment times were 30 minutes, 60 minutes, and 180 minutes, the surface hardness was measured. The results were represented in the following Table 2.

TABLE 2

| Classification | | | |
|---|---|---|---|
| Evaluation | Heating hour | Comp. Ex. 2 | Example 1 |
| Evaluation of | 30 minutes | 1.10 Ω | 0.38 Ω |
| contact resistance | 60 minutes | 1.08 Ω | 0.35 Ω |
| | 180 minutes | 0.83 Ω | 0.23 Ω |
| Evaluation of | 30 minutes | 2H | 3H |
| pencil hardness | 60 minutes | 2H | 3H |
| | 180 minutes | 2H | 3H |

Referring to Table 2, it was confirmed that a contact resistance of Example 1 in which a size of conductive particles was 0.7 μm was lower than that of Comparative Example 2 having a particle size of the conductive particles of 0.3 μm. It was confirmed that as described with FIGS. 5A and 5B, when the particle size of the conductive particle was smaller than 0.5 μm, the conductive particles were sintered by the thermal treatment which formed the side line so that the particle sizes were further increased and consequently, the contact resistance was increased. Further, it was confirmed that as the conductive particles having particle sizes less than 0.5 μm were sintered, the binder resin was reduced between the particles so that the hardness of the entire wiring line was degraded.

### Experimental Example 4-Evaluation of Panel Temperature According to Content of Conductive Particles

A content of silver particles of the paste used for Example 1 was changed to measure a maximum temperature of a side unit of the display panel to which the side line was applied. The results were represented in the following Table 3.

TABLE 3

| Content of silver particles | Maximum panel |
|---|---|
| (wt %) | temperature (° C.) |
| 70 | 100 |
| 73.5 | 57 |
| 77.5 | 50 |
| 80 | 48 |
| 82.5 | 47 |
| 85 | 46 |
| 87.5 | — |

Referring to Table 3, when the content of the conductive particles satisfied 72 wt % to 85 wt % based on a sum of the conductive particles and the binder resin, it was confirmed that a resistance of the formed wiring line was reduced to reduce the heat generated on the panel. The display device and the multi-panel display device according to various exemplary aspects of the present disclosure may be described as follows.

The exemplary aspects of the present disclosure can also be described as follows:

According to an aspect of the present disclosure, there is provided a display device, comprises a first substrate including an active area and a non-active area enclosing the active area, a display unit including an organic light emitting diode disposed on an upper surface of the first substrate, a plurality of signal lines disposed on the upper surface of the first substrate and electrically connected to the display unit, a plurality of link lines disposed below the first substrate, and a plurality of side lines disposed on a side surface of the first substrate and connecting the plurality of signal lines and the plurality of link lines. The plurality of side lines includes a conductive particle having a particle size of 0.5 μm to 1 μm.

The plurality of side lines may further include a binder resin.

The plurality of side lines may include the conductive particles of 72 wt % to 85 wt % based on a sum of the conductive particle and the binder resin.

The plurality of side lines may include a conductive part formed by sintering the conductive particles and a resin part formed by curing the binder resin.

The display device may further comprise a protective layer which is formed as one layer to enclose all side surfaces of the first substrate and cover all the plurality of side lines or is patterned so as to correspond to each of the plurality of side lines.

The display device may further comprise a second substrate disposed on the display unit so as to be opposite to the first substrate, the first substrate may protrude outwardly from the second substrate and the plurality of signal lines is disposed on the protruding first substrate, and the plurality of side lines is disposed to be in contact with exposed upper surface and side surface of the plurality of signal lines.

The display device may further comprise a third substrate disposed below the first substrate, the plurality of link lines may be disposed on a lower surface of the third substrate, the plurality of side lines may be disposed to cover the plurality of signal lines, the first substrate, the third substrate, and side surfaces of the plurality of link lines.

According to an aspect of the present disclosure, there is provided a multi-panel display device. The multi-panel display device comprise a plurality of display devices disposed to be adjacent to each other. Each of the plurality of display devices includes a first substrate including an active area and a non-active area enclosing the active area, a display unit including an organic light emitting diode disposed on an upper surface of the first substrate, a plurality of signal lines disposed on the upper surface of the first substrate and is electrically connected to the display unit, a plurality of link lines disposed below the first substrate, a plurality of side lines disposed on a side surface of the first substrate and connecting the plurality of signal lines and the plurality of link lines, and a protective layer covering the plurality of side lines and includes a black material. The plurality of side lines including a conductive particle having a particle size of 0.5 μm to 1 μm.

The plurality of side lines may further include a binder resin, and the plurality of side lines may include the conductive particles of 72 wt % to 85 wt % based on a sum of the conductive particle and the binder resin.

The plurality of side lines may include a conductive part formed by sintering the conductive particles and a resin part formed by curing the binder resin.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a first substrate including an active area and a non-active area enclosing the active area;
a display unit including an organic light emitting diode disposed on an upper surface of the first substrate;
a plurality of signal lines disposed on the upper surface of the first substrate and electrically connected to the display unit;
a plurality of link lines disposed below the first substrate; and
a plurality of side lines disposed on a side surface of the first substrate and connecting the plurality of signal lines and the plurality of link lines,
wherein the plurality of side lines includes a conductive particle having a particle size of 0.5 μm to 1 μm.

2. The display device according to claim 1, wherein the plurality of side lines further includes a binder resin.

3. The display device according to claim 2, wherein the plurality of side lines includes the conductive particle of 72 wt % to 85 wt % with respect to a sum of the conductive particle and the binder resin.

4. The display device according to claim 2, wherein the plurality of side lines includes a conductive part formed by sintering the conductive particles and a resin part formed by curing the binder resin.

5. The display device according to claim 1, further comprising a protective layer which is formed as one layer to enclose all side surfaces of the first substrate and cover all the plurality of side lines or is patterned so as to correspond to each of the plurality of side lines.

6. The display device according to claim 1, further comprising a second substrate disposed on the display unit and facing the first substrate,
wherein the first substrate protrudes outwardly from the second substrate and the plurality of signal lines is disposed on the protruding first substrate, and the plurality of side lines is disposed to be in contact with exposed upper surface and side surface of the plurality of signal lines.

7. The display device according to claim 1, further comprising a third substrate disposed below the first substrate,
wherein the plurality of link lines is disposed on a lower surface of the third substrate, the plurality of side lines is disposed to cover the plurality of signal lines, the first substrate, the third substrate, and side surfaces of the plurality of link lines.

8. A multi-panel display device, comprising:
a plurality of display devices disposed to be adjacent to each other,
wherein each of the plurality of display devices includes:
a first substrate including an active area and a non-active area enclosing the active area;
a display unit including an organic light emitting diode disposed on an upper surface of the first substrate;
a plurality of signal lines disposed on the upper surface of the first substrate and electrically connected to the display unit;
a plurality of link lines disposed below the first substrate;
a plurality of side lines disposed on a side surface of the first substrate and connecting the plurality of signal lines and the plurality of link lines; and
a protective layer covering the plurality of side lines and including a black material,
wherein the plurality of side lines includes a conductive particle having a particle size of 0.5 μm to 1 μm.

9. The multi-panel display device according to claim 8, wherein the plurality of side lines further includes a binder resin, and the plurality of side lines includes the conductive particle of 72 wt % to 85 wt % with respect to a sum of the conductive particle and the binder resin.

10. The multi-panel display device according to claim 8, wherein the plurality of side lines includes a conductive part formed by sintering the conductive particles and a resin part formed by curing the binder resin.
